(19) United States
(12) Patent Application Publication
(10) Pub. No.: US 2016/0359096 A1
(43) Pub. Date: Dec. 8, 2016

(54) NANOSTRUCTURED SILICON WITH USEFUL THERMOELECTRIC PROPERTIES

(71) Applicants: The Regents of The University of California, Oakland, CA (US); The University of Massachusetts, Boston, MA (US)

(72) Inventors: Peidong Yang, Kensington, CA (US); Jinyao Tang, Milbrae, CA (US); Hung-Ta Wang, Tuscaloosa, AL (US); Thomas P. Russell, Amherst, MA (US); Dong-Hyun Lee, Amherst, MA (US)

(21) Appl. No.: 15/176,087

(22) Filed: Jun. 7, 2016

Related U.S. Application Data
(63) Continuation of application No. 13/430,558, filed on Mar. 26, 2012, now abandoned.
(60) Provisional application No. 61/467,353, filed on Mar. 24, 2011.

(51) Int. Cl. H01L 35/34; H01L 35/32; C01B 33/021

(52) U.S. Cl. CPC H01L 35/34; C01B 33/021; H01L 35/32; C01P 2004/20; C01P 2006/32; C01P 2006/40; B82Y 40/00

(57) ABSTRACT

The invention provides for a nanostructured silicon or holey silicon (HS) that has useful thermoelectric properties. The invention also provides for a device comprising the nanostructured silicon or HS. The HS can be placed between two electrodes and used for thermoelectric power generation or thermoelectric cooling.

### CROSS-REFERENCE TO RELATED APPLICATIONS

This application is a continuation of U.S. patent application Ser. No. 13/430,558, filed Mar. 26, 2012, titled NANOSTRUCTURED SILICON WITH USEFUL THERMOELECTRIC PROPERTIES, which claims priority to U.S. Provisional Patent Application Ser. No. 61/467,353, filed Mar. 24, 2011. The benefit of each of these prior applications is claimed, and each of these applications is incorporated herein by reference in its entirety and for all purposes.

### STATEMENT OF GOVERNMENTAL SUPPORT

The invention described and claimed herein was made in part utilizing funds supplied by the U.S. Department of Energy under Contract Nos. DE-AC02-05CH11231 and DE-FG02-96ER45612, and by the National Science Foundation under Grant No. DMR-0820506. The government has certain rights in this invention.

### FIELD OF THE INVENTION

This invention relates generally to nanostructured silicon.

### BACKGROUND OF THE INVENTION

Worldwide, more than 60 percent of all energy is wasted in the form of waste heat from power plants, industrial processes, and vehicles. It was estimated that in 2005 the U.S. alone has 100 gigawatts of electrical capacity in the form of waste heat, which annually could produce 742 terawatt hours of power. It is estimated that the U.S. consumes 100 quads (100 quadrillion BTUs) of energy a year and 55 to 60 percent of it gets dissipated as waste heat. DOE studies suggest US industries waste enough heat to harvest an estimated 200,000 MWe from the processes, nearly 20% of total present US generation capacity. As such, waste heat has been receiving increased interest as a latent source of power.

The market for thermoelectric energy harvesting, cooling, and refrigeration, has been estimated at $125 billion. To date, the big challenge has been cost. Most ongoing waste heat projects is based on traditional turbine engine technology and cost between $5 million to $50 million, which is too high for most to pay out of capital budgets.

The high efficiency thermoelectrics technology holds great promise to unlock this hidden source of power as well as to drastically reduce greenhouse gas emissions. With new technologies, it might be possible to harvest much of the wasted heat produced by everything from computer processors to car engines and electric power plants, and convert it into usable electricity.

Solid state thermoelectric module have drawn extensive attention on this issue because of the compatibility with large scale heat engine as well as the uniqueness of application in dimension-limit field, such as automobile thermoelectrics and photovoltaic/thermoelectric hybrid.

The major challenge is to improve module efficiency which is mainly attributed to material thermoelectric (TE) quality. The quality is defined by the figure of merit, ZT, which consist of Seebeck coefficient, electrical conductivity, environment absolute temperature and thermal conductivity. ZT enhancement (>1) has been dramatically advanced in the last decade by nanoengineering conventional heavy metal compounds, such as Bi₂Te₃, Sb₂Te₃, or other related alloy. For example, the most widely used thermoelectric material, Bi₂Te₃, has figure of merit ZT(=S²σT/k)˜1 at room temperature. However, it is not suitable for large scale engineering due to the limited availability and high manufacturing cost.

On the other hand, silicon, as the most abundant material with enormous knowledge, had never been considered as TE material due to its high thermal conductivity (150 W/m·K), mainly attributed to lattice vibration (kph). Porous silicon (PS) with randomly distributed and intertwined pores could achieve extremely low thermal conductivity down to 0.1 W/m·K; but the electronic structure of the disordered structure is also severely deteriorated and thus yields very poor electrical conductivity and low ZT. It has been found that thin and rough Silicon nanowires show surprisingly decent ZT(˜0.5), however, its weak mechanical strength and strong dimension dependence remain as obstacles for applications in industry.

### SUMMARY OF THE INVENTION

The invention provides for a nanostructured silicon or holey silicon (HS) that has useful thermoelectric properties. The invention also provides for a device comprising the nanostructured silicon or HS. In some embodiments of the invention, the HS is doped with a suitable dopant. A suitable dopant is boron.

In some embodiments of the invention, the HS is a thin film or membrane. The thin film or membrane can have a thickness of about 100 nm. In some embodiments of the invention, the HS is a thin single-crystalline silicon membrane.

In some embodiments of the invention, the HS has a hexagonal holey pattern of equal to or more than about 55 nm. In some embodiments of the invention, the HS has a hexagonal holey pattern of equal to or more than about 140 nm. In some embodiments of the invention, the HS has a hexagonal holey pattern of equal to or more than about 350 nm. In some embodiments of the invention, the HS has a hexagonal holey pattern of from about 55 nm to about 350 nm. In some embodiments of the invention, the HS has at least 35% porosity. In some embodiments of the invention, the HS has ZT value is equal to or more than about 0.4 at room temperature. In some embodiments of the invention, the HS has ZT value is equal to or more than about 0.6 at room temperature.

In some embodiments of the invention, the HS comprises a two dimensional holey structured thin film with ordered or random pores. The pores can be of any suitable shape, such as hexagons. The pitch and neck of the pores can be of any suitable lengths. In some embodiments of the invention, the HS has good mechanical strength and similarly low thermal conductivity, while maintains sufficient electrical quality. Any HS can be measured for sufficiently low thermal conductivity and sufficient electrical quality using the methods described herein.

In some embodiments of the invention, by reducing the pitch of hexagonal holey pattern down to 55 nm with 35% porosity, the HS thermal conductivity is reduced by more than 100-fold and approaches the amorphous limit. This result is comparable with the best value recorded in nanowire system, and overall ZT around 0.4 has been achieved at room temperature with higher value expected at elevated temperature. The strong mechanical strength as well as reliable performance makes HS a much more attractive material for thermoelectric application.

Lower thermal conductivity is observed as smaller pitch size holes incorporated in silicon. The thermal conductivity of 55 nm-pitch HS is reduced to as low as ˜1 W/m·K without significantly sacrificing its thermoelectric power factor. The HS behaves as phonon glass and electron crystal, and its overall ZT is ˜0.4 at room temperature which is likely to be further improved by optimizing the doping procedure as well as pitch size/porosity.

In the present invention, by incorporating holes with diameter around 100 nm inside silicon film, suppression of thermal conductivity is observed. HS can be created by nanosphere lithography. Holey silicon ribbons are formed by duplicating the shape of assembled nanobeads. These ribbons can be lifted-off and transferred to thermal measurement devices, or directly incorporated into thermal devices. Example 1 described herein illustrates the importance of the phonon scattering center arrangement in thermal transport, and provides a guideline to better thermoelectric material design.

The HS can be fabricated by any suitable method, such as nanosphere lithography or block-copolymer lithography (FIGS. 10 and 11, respectively). One suitable method is described herein in Example 1.

The HS can be placed between two electrodes and used for thermoelectric power generation or thermoelectric cooling In some embodiments of the invention, the device is electric generator or a heat pump. One skilled in the art should know the additional features of such devices and their use thereof. The invention also provides for a method of creating an electric current using the device of the present invention. The invention also provides for a method of decreasing the temperature of a locality using the device of the present invention.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 shows the structural characterization of 55 nm pitch holey silicon ribbon. a. atomic force microscopy (AFM) (topography) image of reconstructed surface of S4VP(69 k)/hPS(14 k) on SOI substrate with mixing ratio of 60/40 (wt/wt). Block copolymer (BCP) holey pattern uniformly covers entire 2×2 cm substrate except boundary region, and consistent uniformity is obtained for 55 nm pitch holey silicon fabrication. Inset, Fourier-transform patterns of the AFM image indicate long-range ordering b. An SEM image of holey silicon film after deep reactive-ion etching (DRIE). 55 nm pitch holey structure is successfully transferred from BCP lithography. c. Bright field TEM image of a section of 100 nm (thickness)×2.5 μm (width)×30 μm (length) ribbon. The porosity is estimated as ˜35% through entire 30 μm length. The selected area electron diffraction pattern (inset) indicates single crystalline <100> face which is identical with the starting SOI wafer. d. High-resolution TEM of the edge of a hole, which show ˜2 nm native oxide thickness on the surface. Scale bars for a-c are 1 μm and d is 2 nm.

FIG. 2 shows the thermal conductivity of holey silicon ribbons with different pitch. a. SEM image of a Ni-bonded 55 nm-pitch holey silicon ribbon bridging between two suspended symmetrical SiNₓ membranes. Same Pt coil on each membrane are heating and sensing unit respectively for ribbon thermal conductivity measurements. The scale bar is 10 μm. b-d are SEM images for 350 nm pitch, 140 nm pitch and 55 nm pitch Holey Silicon ribbon from intrinsic SOI substrates, The scale bar for b-d is 500 nm. e. temperature dependent k of nonholey, 350 nm, 140 nm, and 55 nm pitch holey silicon ribbon. Error bars for all three holey ribbons are smaller the data point in this plot. f. an enlarged plot of e including a curve of amorphous silica for comparisons.

FIG. 3 shows the thermoelectric properties and ZT calculation for 55 nm pitch holey silicon ribbon. a. temperature-dependent ρ (dark square) and S (light square) of a boron doped 55 nm pitch holey silicon ribbon. b. ratio of highly doped control silicon k to that of a highly doped 55 nm pitch holey silicon ribbon. The dark square curve is taken by non-holey ribbon while the open square is in comparison with bulk (1.7×10¹⁹ cm⁻³, As-doped, from ref 7). Light square show the ratio of power factor of highly doped non-holey ribbon to the one of 55 nm pitch holey ribbon. d. power factor (light square) of a 55 nm pitch holey silicon ribbon and ZT (dark square) using the measured k by another 55 nm pitch holey ribbon, boron-doping annealed at same batch. With consideration of measurement error from both power factor 20% and k 6%, the ZT show 25% uncertainty at 95% confidence.

FIG. 4 shows the illustration of Holey Silicon fabrication based on nanosphere lithography. a, Polystyrene spheres are assembled on SOI substrate as monolayer. b, Nano spheres are etched with mild oxygen plasma for uniform separation. c, 5 nm chromium is deposited followed by sphere lift-off in acetone to form holey structured chromium mask. d, DRIE etched Holey Silicon through mask and Cr mask is finally removed.

FIG. 5 shows the illustration of Holey Silicon fabrication based on block copolymer (BCP) assembly. a, Holey structured block copolymer film coated on SOI substrate. b, 5 nm thick holey structured Cr mask is obtained by e-beam evaporation at 60° tilted angle. c, BCP film is etched by oxygen plasma, and Cr mask is remained for silicon DRIE etching. d, After Cr is removed, Holey Silicon is tailored into ribbons using standard photolithography.

FIG. 6 shows AFM images (3 μm×3 μm, height mode) of reconstructed surface of S4VP(69 k)/hPS(14 k) with various mixing ratios. a, neat, b, 95/5 (wt/wt), c, 90/10 (wt/wt), d, 80/20 (wt/wt), e, 70/30 (wt/wt), and f, 60/40 (wt/wt), respectively.

FIG. 7 shows the thermal conductivity of Holey Silicon ribbon with different width. No clear dependence of thermal conductivity on ribbon width is observed which implies the dominate surface scattering on the incorporated hole surface overwhelmed the ribbon edge surface.

FIG. 8 shows the thermal contact resistance calibration. a. SEM image of covalent bonded device at SiNₓ pad to silicon ribbon junction. b. SEM image of nickel bonded device at bind site. c, Contact resistance, defined by the total thermal resistance difference of two measured non-holey silicon ribbons gradually increases toward lower temperature and peaks as 5K/μW at 50K. d, Contact Resistance to total resistance ratio of 55 nm pitched Holey Silicon ribbon. Contact Resistance is around 3% at room temperature and decreases with lowering temperature, so can be neglected throughout the temperature range.

FIG. 9 shows Holey Silicon ribbon thermopower and electrical conductivity measurement. a, SEM image of a typical device used for electrical measurement. The left heating coil is used to create uniform temperature gradient. Two inner Pt electrodes are used for seebeck voltage measurement and temperature sensing, while all four electrodes are used for four probe p measurement. b, Typical plot of seebeck voltage vs temperature difference. c, I-V plot by four probe electrical resistance measurement. b, and c plots are for the 55 nm pitch ribbon shown in FIG. 3.

FIG. 10 shows the steps of fabricating HS using nanosphere lithography.

FIG. 11 shows the steps of fabricating HS using block copolymer lithography.

FIG. 12 shows (A) a 3-dimensional view of a HS, and (B) the definition of the lengths of pitch (“p”) and neck (“n”).

### DETAILED DESCRIPTION

Before the present invention is described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “and”, and “the” include plural referents unless the context clearly dictates otherwise. Thus, for example, reference to “a ribbon” includes a plurality of such ribbons, and so forth.

These and other objects, advantages, and features of the invention will become apparent to those persons skilled in the art upon reading the details of the invention as more fully described below.

### Devices Comprising the Nanostructured or Holey Silicon

The present invention provides for a device comprising the nanostructured silicon or HS. The HS contacts a first electrode and a second electrode. When the device is in operation, the first electrode and the second electrode are in electrical communication.

In some embodiments of the invention, the method of creating an electric current comprises: providing a device of the present invention, and setting up a temperature gradient between the first and second electrodes, such that an electric current is created that flows from the first electrode to the HS and through the HS to the second electrode.

In some embodiments of the invention, the device comprises a plurality of array of HS.

In some embodiments of the invention, the method of decreasing the temperature of a locality comprises: providing a device of the present invention, and applying an electric current through the device; such that the temperature of the first electrodes is decreased, wherein the first electrode is at or near the locality, and the temperature of the second and third electrodes is increased.

In some embodiments, the device is such that when there is a difference in temperature between the first electrode and the second electrode such that an electric current is created through the HS.

When the temperature of the first electrode is increased relative to the temperature of the second electrode, or the temperature of the second electrode is decreased relative to the temperature of the first electrode, an electric current is created in which there is an electric current flowing from the first electrode to the HS, and through the HS to the second electrode. In some embodiments of the invention, the method of using the device described above further comprises maintaining a temperature difference (or temperature gradient) between the first and second electrodes, such that the electrode with the higher temperature continues to have a higher temperature. When the device is in operation, the first electrode and the second electrode are in electrical communication.

The electrodes can comprise any suitable material, such as, Pt, Au, Ti, or the like.

The difference in temperature between the first and second electrodes is 1 degree or more, 5 degrees or more, 10 degrees or more, 50 degrees or more, 100 degrees or more, or 200 degrees or more. Any temperature is suitable as long as the temperature of each electrode does not result in the melting of any component of the device, or the interference of the desired electric current.

The electric current can be passed through or captured or stored by a capacitor, or the electric current can be used to drive any electrically driven machine that uses a direct current, such as a motor.

The device of the invention can be a thermoelectric power generator or thermoelectric cooler. The device of the invention can be used for thermoelectric power generation or thermoelectric cooling, such as for computer chip cooling.

The invention having been described, the following examples are offered to illustrate the subject invention by way of illustration, not by way of limitation.

### Example 1

Harvesting waste heat for electrical power generation is one of the important clean energy resources that could has potentially impact on entire future trends of environmental protection and energy security. Solid state thermoelectric module have drawn extensive attention on this issue because of the compatibility with large scale heat engine as well as the uniqueness of application in dimension-limit field, such as automobile thermoelectrics, or photovoltaic/thermoelectric hybrid (1-3). The major challenge is to improve module efficiency which is mainly attributed to material thermoelectric (TE) quality defined by the figure of merit, ZT=S²σT/k, where S is Seebeck coefficient, σ is electrical conductivity, T is environment absolute temperature, and k is thermal conductivity. ZT enhancement (>1) has been dramatically advanced in the last decade by nanoengineering conventional heavy metal compounds, such as Bi₂Te₃, Sb₂Te₃, or other related alloy (4-6). On the other hand, thin and rough Silicon nanowires show surprisingly decent ZT(˜0.5) which makes silicon become candidate for future large scale thermoelectric application (7, 8). However the weak mechanical strength and its strong dimension dependence remain as big challenge for nanowire application. Here, we explore the thermoelectric property of two dimensional holey structured thin films, named as Holey Silicon, fabricated by nanosphere lithography or block-copolymer lithography. By reducing the pitch of hexagonal holey pattern down to 55 nm with 35% porosity, the Holey Silicon thermal conductivity is reduced by more than 100-fold and approaches the amorphous limit. This result is comparable with the best value recorded in nanowire system with overall ZT around 0.4 is achieved at room temperature. The strong mechanical strength as well as reliable performance makes Holey Silicon a more attractive material for thermoelectric application.

Solid state thermoelectric (TE) phenomenon converts energy between heat and electricity, which is commonly applied for both electrical power generation and refrigeration (1, 9). The most widely used thermoelectric material, Bi₂Te₃, has figure of merit ZT(=S²σT/k)˜1 at room temperature, however, it is not suitable for large scale engineering due to the limited availability and high manufacturing cost. Silicon as the most abundant material with enormous knowledge had never been considered as TE material because of its high thermal conductivity (150 W/m·K) (10), mainly contributed from lattice vibration (kₚₕ). On the other hand, porous silicon (PS) with randomly distributed and intertwined pores could achieve extremely low thermal conductivity down to 0.1 W/m·K (11, 12), however the electronic structure of this disordered porous silicon is also severely deteriorated which yields very poor electrical conductivity and low ZT(13). Recent works show that by either reducing silicon volume into one dimensional nanowire with diameter much smaller than the bulk phonon mean free path or substantially roughening the nanowire surface, almost 100-fold of suppression in lattice thermal conductivity is observed and ZT is dramatically enhanced from 0.01 as bulk to 0.4˜0.6 (7, 8). Since the nanowire TE performance is highly depending on its diameter/size and microscopic surface morphology (14, 15), synthesis of high density and highly uniform nanostructures will be the crucial challenge toward the realization of high performance silicon based TE module. Here, we reported the ordered porous silicon, named as Holey Silicon in contrast to PS, with good mechanical strength and similarly low thermal conductivity while sustain sufficient electrical quality. To demonstrate the effect of nano-holey structure to the TE transport properties, Holey Silicon with pitch size of 350 nm, 140 nm and 55 nm are prepared respectively by either nanosphere lithography (NSL) or block copolymer (BCP) self-assembly. Our results show that the thermal conductivity of 55 nm-pitch Holey Silicon is reduced to as low as ˜1 W/m·K without significantly sacrificing its thermoelectric power factor S²σ. The Holey Silicon behaves as phonon glass and electron crystal (9), and its overall ZT is ˜0.4 at room temperature which is likely to be further improved by optimizing the doping procedure as well as pitch size/porosity.

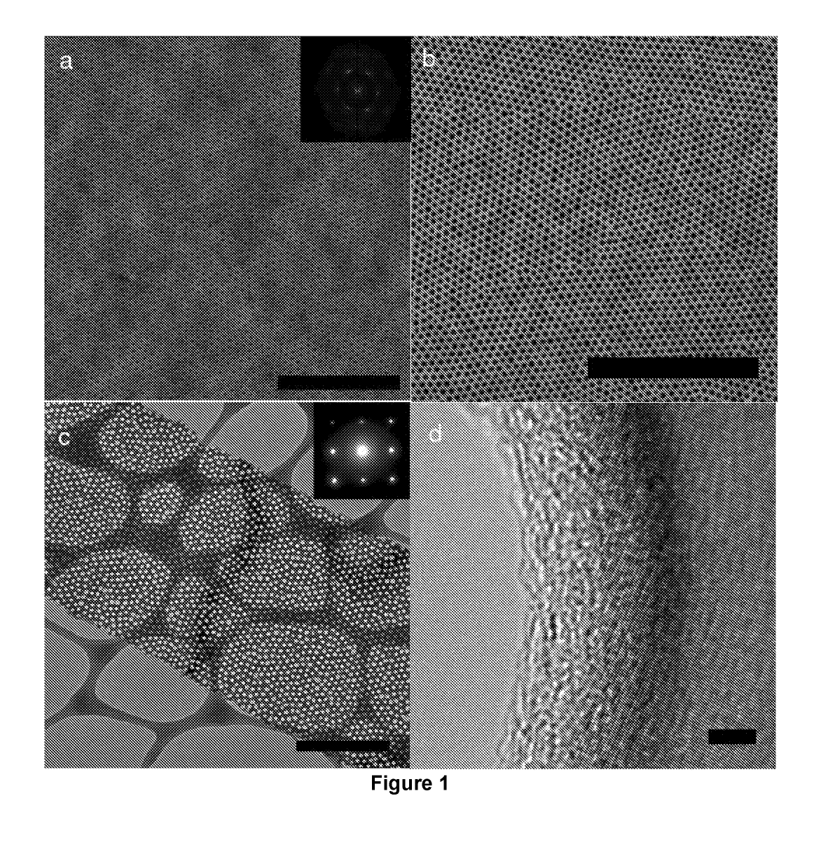

The preparation of large scale Holey Silicon film is based on deep reactive ion etching (DRIE) through thin chromium mask defined by either NSL or self-assembled BCP film and is detailed in supplementary information. Briefly, for 350 nm and 140 nm pitch Holey Silicon, polystyrene nanospheres are assembled into closed-packed monolayer by dip-coating onto silicon-on-insulator (SOI) wafer with 100 nm silicon device layer. Oxygen plasma is then applied to nanospheres until they are separated from each other. The holey structured metal film is then created by e-beam evaporating 5 nm chromium followed by stripping off nanospheres with sonication in acetone. This metal film is served as etching mask to create Holey Silicon in anisotropic DRIE. For 55 nm pitch sized Holey Silicon, polystyrene-block-poly(4-vinylpyridine) (S4VP) copolymer mixed with 40 wt % polystyrene homopolymer are spin coated onto pre-cleaned SOI substrate followed by annealing in tetrahydrofura (THF) vapor. The long-range ordered hexagonally packed holey structure (16) is created by surface reconstructing in ethanol as shown in FIG. 1a and detailed in supplemental information. Holey structured chromium mask is obtained by the shadowing effect of 5 nm chromium deposition with 60 degree titling angle directly onto this holey structured BCP. Oxygen plasma ashing is consequently used to remove the BCP film and only holey Cr film is used as DRIE etching mask to attain Holey Silicon. Typically this method provides 55 nm pitch Holey Silicon with porosity around 30-40% with hole diameter ranging from 25-40 nm. Chromium mask are stripped thoroughly in chromium etchant after the DRIE silicon etching. All Holey Silicon films are finally tailored into 1˜3 μm wide, 20˜50 μm long individual ribbons by standard photolithography and then released from substrate by etching off the buried oxide layer in hydrofluoric acid (HF) vapor for transport measurements and SEM/TEM characterization. The SEM and TEM images (FIGS. 1b and 1c) show the Holey Silicon film has uniform hole size and separation with highly ordered hexagonal packing, thus it can be regarded as two dimensional semi-periodic holey structure. In FIG. 1c inset, the electron diffraction pattern confirmed silicon [100] single crystal face throughout the ribbon which is consistent with the starting SOI wafer. The sidewalls of holey edge show a layer of native oxide typically ˜2 nm thick as shown in FIG. 1d.

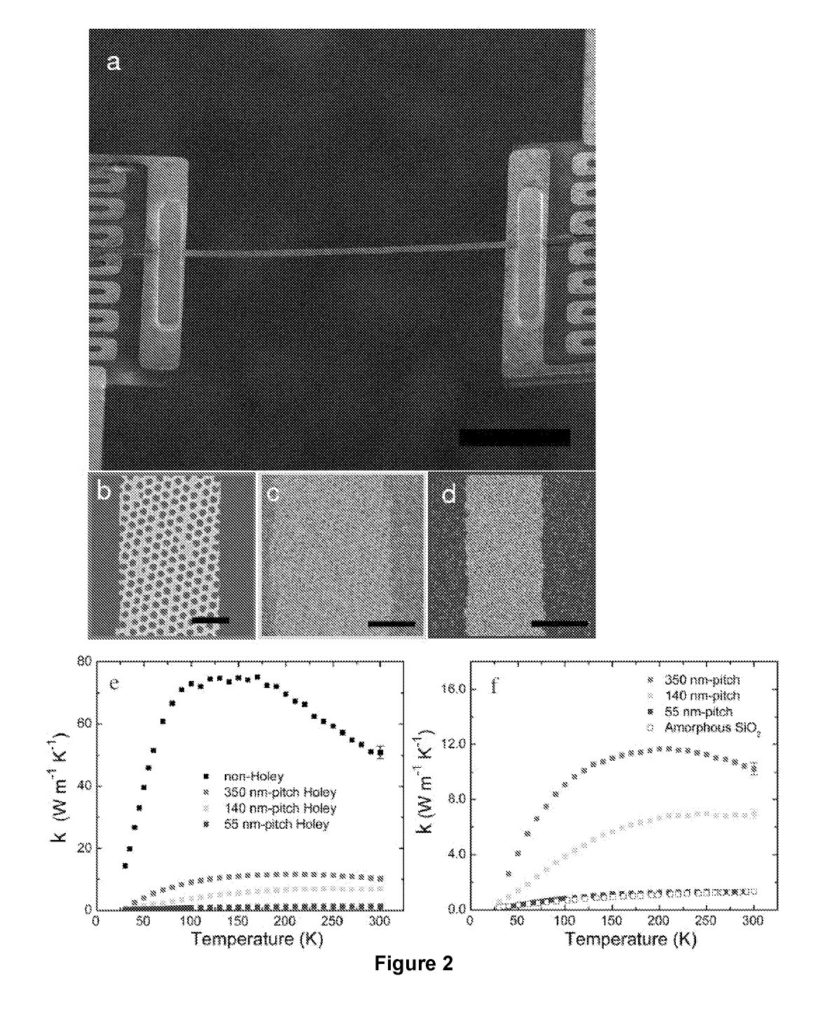

The thermal transport property of the Holey Silicon ribbon is characterized by MEMS devices descried previously (8, 14, 15, 17) which consisted of two suspended silicon nitride (SiNₓ) membranes incorporated with platinum heating/sensing coil and separated by 10 μm to 30 μm. Holey Silicon ribbon is placed between two membranes using micromanipulator and then anchored to the membrane by ˜300 nm nickel bonding patch evaporated through silicon nitride stencil mask (FIG. 2a). The thermal contact resistance is estimated by comparing the thermal conductance of intact silicon ribbon covalently fused to SiNₓ membrane with same geometry and is less than 10% of total resistance for all Holey Silicon ribbon measured here.

FIG. 2b shows the measured thermal conductivity of Holey Silicon with different pitch sizes in comparison with non-holey ribbon. All measured Holey Silicon ribbons are with similar porosity around 35% and we found the Holey Silicon exhibit a pitch dependency of thermal conductivity reduction across the entire temperature range scanned. In contrast to bulk, the phonon mean free path in 100 nm non-holey silicon ribbon is presumably limited by upper and lower boundary and the observed k is comparable with the reported thin film k (18). With incorporation of densely packed holes, k is further reduced by confined cross section in transport channel and additional effective surface scattering. These observations are analogous to single nanowire system where diameter is the dominate factor and extra roughness could further reduce k by diffusive surface scattering (8, 14, 15). Another distinct feature is the peak of thermal conductivity-temperature curve (peak at 25K as bulk) shifted to higher temperature as non-holey ribbon at 130K, 350 nm pitch holey ribbon at 200K, and beyond room temperature for pitch size smaller than 140 nm. All above observations indicate the dimension effect and surface scattering dominate in the samples such that Umklapp scattering is negligible in Holey Silicon ribbon with pitch smaller than 140 nm.

TABLE 1
Summary of the HS geometry and the
thermal conductivity at 300 K^{a}.

| | avg. pitch, p | avg. neck, n | avg. porosity, φ | κ |
|---|---|---|---|---|
| | (nm) | (nm) | (%) | (Wm⁻¹ K⁻¹) |
| nonholey | | | 0 | 50.9 ± 2.0 |
| nonholey* | | | 0 | 47.6 ± 1.7 |
| 350-pitch | 350 | 152 | ~35 | 10.23 ± 0.44 |
| 140-pitch | 140 | 59 | ~35 | 6.96 ± 0.34 |
| 55-pitch | 55 | 23 | ~35 | 2.03 ± 0.07 |
| 55-pitch* | 55 | 23 | ~35 | 1.73 ± 0.06 |

^{a}Note:
All ribbons are 100 nm in thickness. All κ are normalized by φ. Samples are all intrinsic (phosphorus doped, ~3 × 10¹⁴ cm⁻³), except *(boron doped, ~5 × 10¹⁹ cm⁻³) used for ZT.

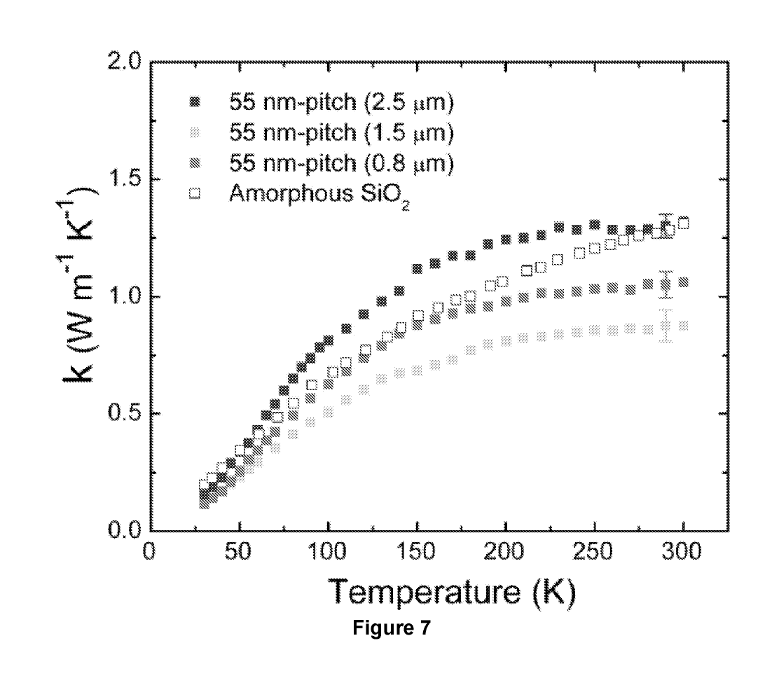

Moreover, FIG. 2c shows the lowest thermal conductivity of the 55 nm pitch Holey Silicon have reached the low thermal conductivity of amorphous silicon dioxide. Table 1 summarizes the room temperature conductivity of all the silicon ribbons for comparison. A consistent value, ranging from 0.9 to 1.3 W/m·K at room temperature, have been measured among multiple samples with different width (see FIG. 7). Pushing the thermal conductivity of single crystal silicon down to amorphous solid limit is attainable in silicon nanowire system (7, 8). In such cases, material dimension is the predominant factor that screens the broad phonon spectrum from bulk, practically for long wavelength phonon. In addition, surface scattering could behave more diffusively from specular mode by diminishing the wire diameter coupled with rough surface (15). These speculated mechanisms are completely different to systems in amorphous solid or disordered crystal where the mean free path could be reduced to near interatomic distance (19). In Holey Silicon system, phonon transportation path is serpentine around the quasi-periodic holes with a low frequency and sharp spectrum that could effectively scatter long wavelength phonon, while the random roughness on the hole surface created by DRIE process have much higher frequency and broader spectrum that can scatter short wave length phonon more effectively. Besides, the quasi-periodic holey structure likely constructs a phononic crystal where a phononic bandgap might filter out partial phonons which are still effective in 100 nm non-holey ribbon. Finally, lattice waves could transform form diffusive (Ohmic behavior) to frozen state as suggested as Anderson localization (20, 21). These judgments are still quite elusive and further experiments are certainly needed to verify the detailed mechanisms in our Holey Silicon system. We did not observe significant thermal conductivity variation in ribbons with different width ranging from 0.8 μm to 2.5 μm as shown in FIG. 7 which suggests the phonon mean free path is already limited by the small pitch sized holey structure. This is a crucial benefit for future application compared with nanowire system in which the performance varies greatly with its diameter and surface roughness. Note that our experimental k value is lower than theoretical prediction (22) and this discrepancy might be attributed to couple reasons, such as hexagonal holey array unlike square array used in the simulation model, variety of hole defects induced by nano-assembly, and etching induced roughness on the hole sidewall surface, etc.

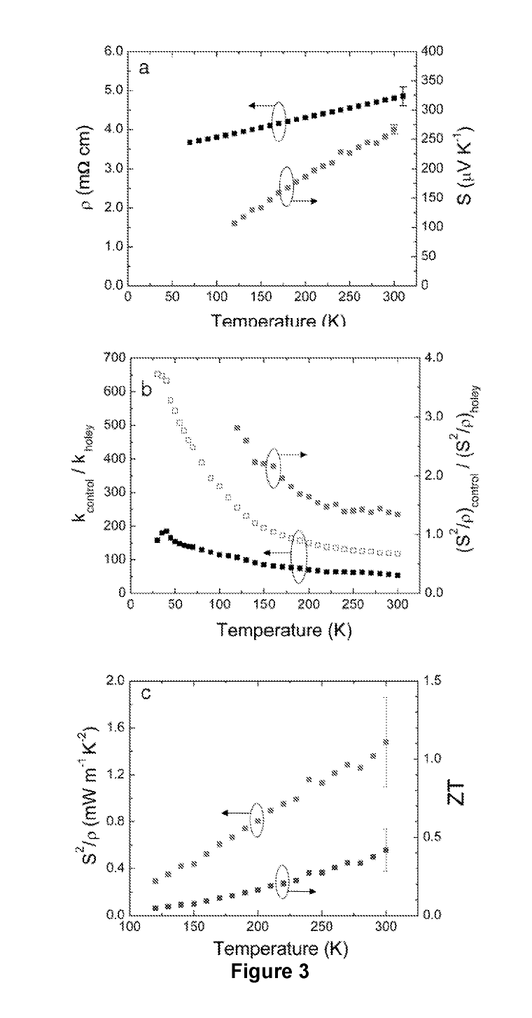

Since the electron mean free path in highly doped silicon (˜1×10¹⁹ cm⁻³) optimal for thermoelectric application is just around 1 nm, incorporating holes with tens of nm pitch should in principle have limited impact on Holey Silicon electrical properties (S²/ρ) thus enhance its ZT. With such low thermal conductivity observed in 55 nm pitch Holey Silicon, we consequently select this version for ρ, S measurements and ZT evaluation. Intrinsic Holey Silicon ribbons are subjected to gas phase boron doping at 830° C. to achieve doping level around 5×10¹⁹ cm⁻³ and then four probe electrical contacts in parallel with long platinum heating coil are patterned using photolithography for both ρ and S measurements The post-doped Holey Silicon shows thermal conductivity around 1.1 W/m·K at room temperature which is not significantly different with intrinsic sample. This may be due to the cancellation of electronic thermal conductivity kₑ=L·T·σ˜0.4 W/m·K (defined by Wiedemann-Franz law) by point defects (both impurities and holes). For comparison, FIG. 3b plots the property ratio between holey and nonholey ribbon for both thermal conductivity (k) and thermoelectric power factor (S²/ρ). The holey structure shows around 40-120 times suppression on thermal conductivity at room temperature while greater suppression is observed at lower temperature and peak at ˜40K when k of non-holey sample is limited by surface scattering. A moderate deterioration of thermoelectric power factor S²σ is also observed as compared to close to optimally doped silicon non-holey ribbon and gradually degraded toward lower temperature. The lower thermoelectric power factor mainly comes from lower electrical conductivity. Due to very high surface-to-volume ratio of Holey Silicon, electrical conductivity is highly sensitive to its surface states (23, 24) due to surface depletion. At higher temperature, the surface state trapped carrier can be thermally activated and thus the power factor reduction would be less obvious (25). This issue could be improved by surface passivation to further enhance the overall ZT.

Across the entire temperature range in our measurement, the ZT enhancement factor remains around 50 times compared with non-holey sample with same thickness. From 120K to 300K, the ZT is linearly increasing with temperature and reach 0.4 at 300K. It is known that unlike Bi₃Te₂ whose ZT peak around room temperature, ZT of bulk silicon is monotone increasing up to more than 1000° C. (26), which suggests higher ZT of Holey Silicon is expected at elevated temperature and high temperature operation is relatively favorable.

In conclusion, we have utilized block copolymer self-assembly to fabricate Holey Silicon ribbons with hexagonal packed holes, and the results demonstrated the enhanced thermoelectric performance with ZT up to 0.4 at room temperature. Higher ZT is likely be obtained by optimizing doping level and hole pitch size/porosity. The thermal conductivity approaches amorphous limit which results the significant ZT improvement is observed here. The fundamental phonon transport mechanism underlying this 2-dimensional nano-holey structure is still elusive but such holey structure could be applied to other material system to improve state-of-art thermoelectric module efficiency. Because of the scalability of this technique, an immediate application could be on-chip thermal management for solid state devices, while large scale waste heat salvaging is also highly conceivable by extension into bulk materials system.

### Further Information

1. Holey Silicon Fabrication.

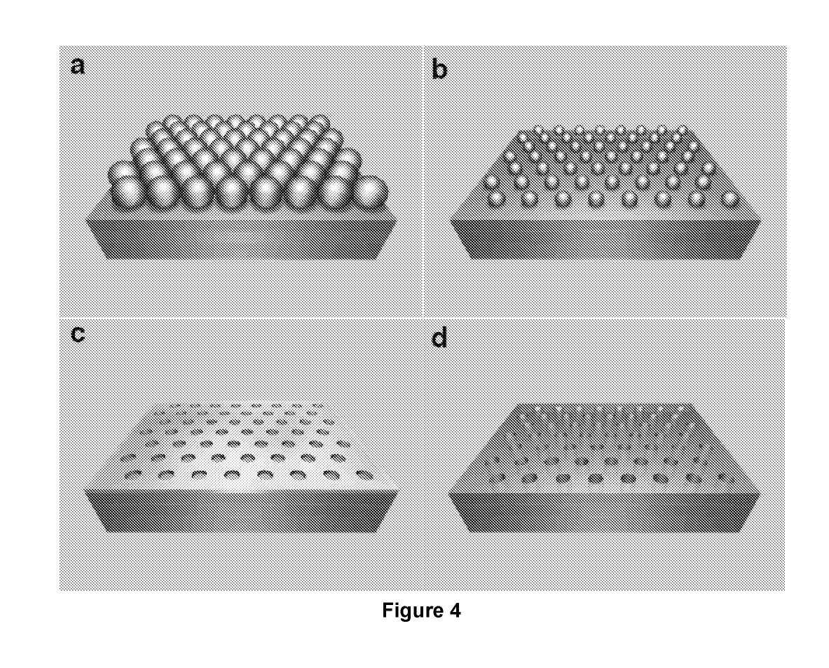

The Holey Silicon ribbons used for transport measurements are patterned by optical lithography and then released from SOI substrate by hydrofluoric acid vapor etching. The SOI wafer consists 100 nm device layer (<100>, 14-22 Ω·cm, Boron doped) with 200 nm buried oxide layer. Nano-holey structure is fabricated by DRIE through thin metal mask (˜5 nm) converted from nano-lithography pattern. FIG. 4 show the schematic of detailed fabrication of 350 nm and 140 nm pitch Holey Silicon ribbons. 350 nm and 140 nm polystyrene spheres (Bangs laboratories, Inc., Fishers, Ind.) are 1:4 diluted with de-ionized water and subjected to 2 min sonication before coating to insure homogeneous sphere suspension. The substrate is cleaned with piranha for 10 mins and rinsed with de-ionized water followed by N₂ blow-dry. Polystyrene spheres are self-assembled into hexagonal monolayer film via a dip coating process at speed around 4 μm/s in a customized dip coater equipped with isolating shield to prevent disturbing from air flow. Throughout the assembly process, line defects and point defects are sometimes observed mostly due to the non-uniformity of sphere size. Weak oxygen plasma (20 W at ˜300 mtorr in the Technics PEII-A plasma system) is then used to etch polystyrene sphere until the desired spacing is obtained. 5 nm chromium, served as silicon etching mask, is deposited with an e-beam evaporator at 2×10⁻⁶ Torr, then the polystyrene spheres are then removed by ultra-sonication in acetone for 5 mins. Silicon etch is performed in a DRIE system, with 600 W (13.56 MHz) applied on coil and 30 W (380 kHz) on substrate. After 6 cycles of 5 second passivation plus 6 second etching, 100 nm silicon layer is completely etched through. The chromium mask is then removed by soaking the sample in chromium etchant (CR-7s, from Cyantek Corp., Fremont, Calif.) for 2 mins at room temperature.

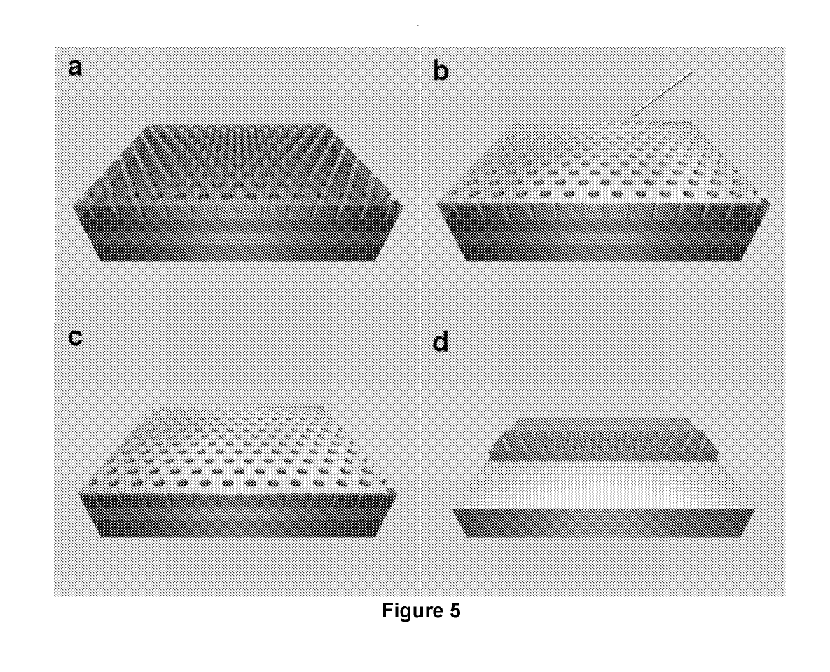

A similar chromium mask conversion method is applied to BCP lithography for fabrication 55 nm pitch Holey Silicon ribbons, as shown in FIG. 5. 55 nm-pitch hexagonal structure is patterned on SOI substrate as stated above. The 5 nm chromium mask is deposited onto this holey structured BCP film by e-beam evaporation at 60 degree titling angle. To insure better etching uniformity, sample is further treated with oxygen plasma to thoroughly remove BCP template in order to ensure the silicon is freshly exposed and can be etched away by following DRIE process. SEM is then used to carefully examine the holey structure and >95% etching uniformity of Holey Silicon is specifically selected for the transport characterizations.

2. Block Copolymer (BCP) Assembly and Characterization.

Polystyrene-block-poly(4-vinylpyridine) (S4VP) copolymer was purchased from Polymer Source Inc. (Montreal, Canada), and used without further purification in this study. Polystyrene homopolymer was synthesized by anionic polymerization. The number average molecular weights (Mₙ) of polystyrene and poly(4-vinylpyridine) were 51 kg/mol and 18 kg/mol, respectively, and the polydispersity (Mₙ/Mₙ) of this BCP was 1.15. The number average molecular weight and the polydispersity of polystyrene homopolymer (hPS) were 14.4 kg/mol and 1.03, respectively. The mixture of S4VP and hPS with various mixing ratios was dissolved in the mixture of toluene and tetrahydrofuran (70/30, v/v). S4VP thin films (˜25 nm) were prepared by spin-coating at 2200 rpm on silicon-on-insulator (SOI) substrates (Soitech, Inc., Bernin, France) The films were solvent-annealed in tetrahydrofuran vapor for 3 hours to induce lateral long-range ordering of BCP microdomains. To generate nanoscopic pores, the surface of S4VP thin films was reconstructed by immersing the substrate into ethanol, which is a good solvent for a minor component block of S4VP.

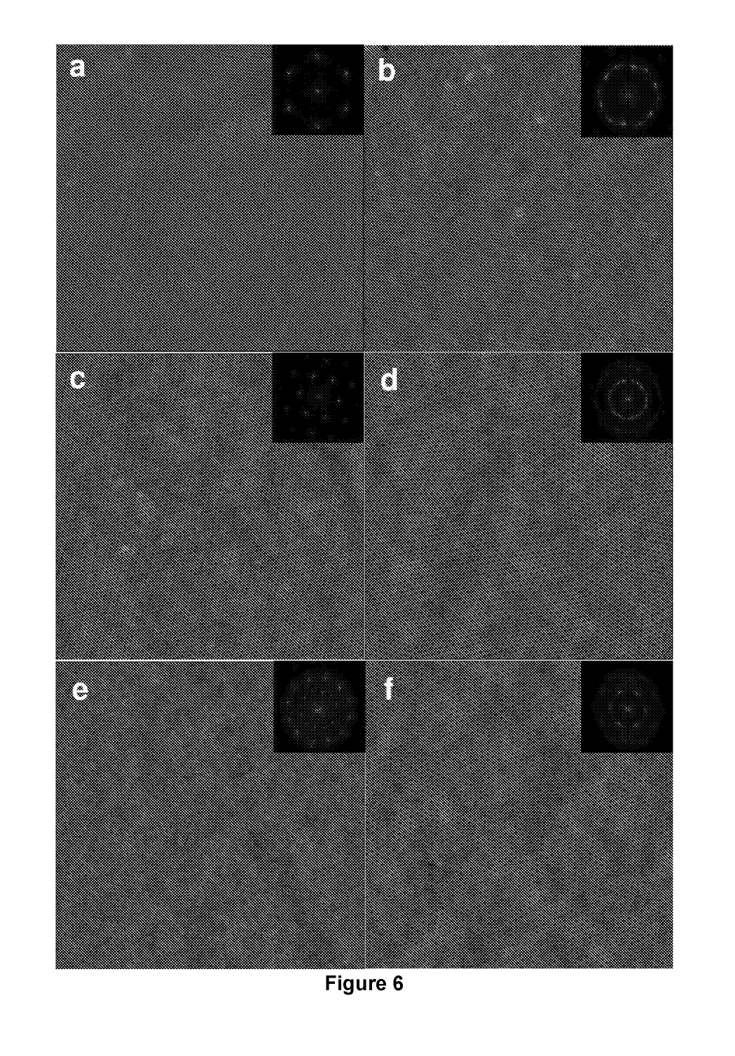

To prevent merging holes during a following DRIE process, it is necessary to spread out the separation distance among cylindrical microdomains of P4VP. As introducing polystyrene (14 k) homopolymer into S4VP(69 k) thin film, separation distance of cylindrical microdomains of P4VP was gradually increased because hPS(14 k) existed selectively in PS matrix of S4VP(69 k) thin film. As shown in FIG. 6, separation distance in neat S4VP(69 k) thin film is about 36.1 nm. By adding hPS(14 k), consequently, it is observed that separation distance of S4VP(69 k)/hPS(14 k) (60/40, wt/wt) was finally increased up to 55 nm. In this study, we selected this 55 nm pitch S4VP thin film (FIG. 6f) as an etching mask to transfer its holey structure to the SOI substrate.

3. Thermal Conductivity Measurement and Thermal Contact Resistance Calibration.

In order to measure Holey Silicon ribbon's thermal conductivity, the fabricated ribbons on SOI chips are released by vapor HF treatment for about 30 seconds, and individual ribbon is then placed between two SiNₓ thermal pads by micromanipulation using sharp tungsten probe tips (GGB Industries) mounted on a scanning stage (Märzhäuser SM 3.25; Märzhäuser Wetzlar GmbH & Co. KG, Wetzlar, Germany). Then the device is mounted on mask aligner (Karl Suss MA6; SUSS MicroTec AG, Garching, Germany) and precisely aligned with prefabricated SiNₓ stencil mask (O. Vazquez-Mena et al., Nano Lett 8, 3675 (2008)). The stencil mask and thermal device are bonded with I-line photoresist (OCG OiR 897-10i). After dried on hotplate at 95° C. for 10 mins, the whole device/stencil chip is transferred into e-beam evaporator for 300 nm nickel deposition under 2×10⁻⁶ torr. The stencil mask is consequently removed from the device simply by mechanical force without any damages to the suspended structure or bonded ribbon. Thermal measurement is conducted with previously reported technique (8; D. Li et al., Applied Physics Letters 83, 2934 (2003)). As shown in FIG. 7, the temperature-dependent thermal conductivities of three 55 nm pitch Holey Silicon ribbons with different width are fairly consistent and close the amorphous limit. Since the incorporated nano-holes have already overwhelmed the surface phonon scattering, no dimension dependence is observed. This is a crucial advantage of Holey Silicon compared to silicon nanowire for reliable, large scale module integration.

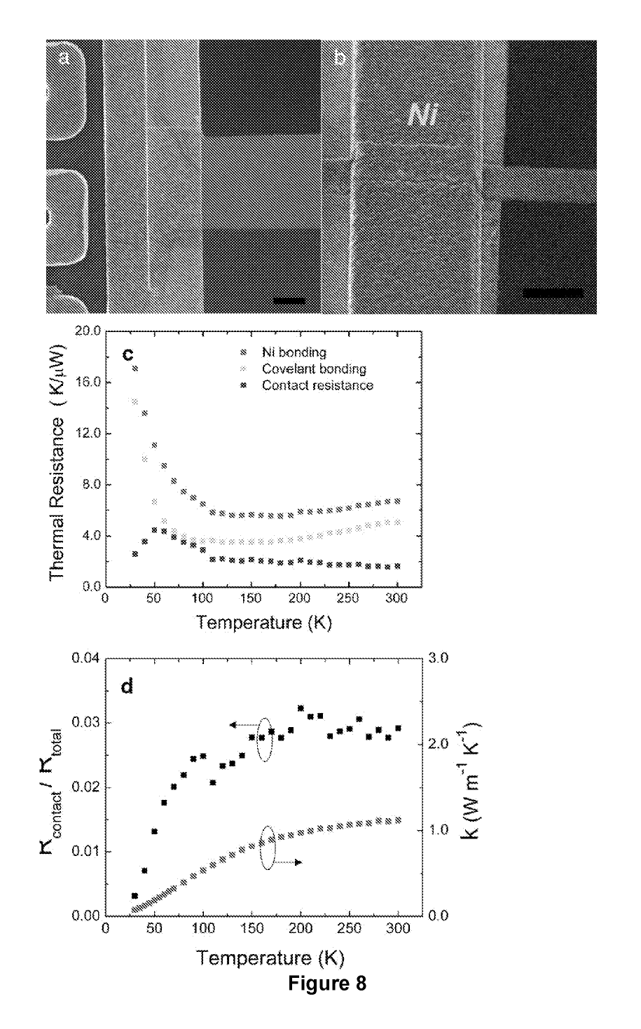

The thermal contact resistance of the nickel bonding is estimated by comparing thermal resistance of 100 nm thick non-Holey silicon ribbon covalently fused to SiNₓ membrane during the thermal device fabrication process (FIG. 8a) with Nickel bonded device (FIG. 8b). Since the covalent bonding should mostly show Thermal boundary resistance (E. T. Swartz, R. O. Pohl, Reviews of Modern Physics 61, 605 (1989)) which is on the order of 1×10⁻⁴ K/μW in this system, it is negligible in the measurement as compared to the silicon ribbon's thermal resistance around 5 K/μW. In order to calibrate the thermal contact resistance of Ni bonding, a 30 um long 1 um wide non-Holey silicon ribbon is bonded to thermal device with sample protocol as described previously, the measured data is then compared with covalently bonding device with same ribbon geometry. As shown in FIG. 8c, the contact resistance is obtained as the total resistance difference of two devices, and is around 1.5 K/μW at room temperature. In consideration of thermal contact resistance in all Holey Silicon ribbon measurements here, total resistance ranging from 15-100 K/μW, measurement error is around 10% for 350 nm pitch Holey Silicon, 6% for 140 nm pitch Holey Silicon around 3% for 55 nm pitch Holey Silicon, shown in FIG. 8d.

4. Electrical Measurement.

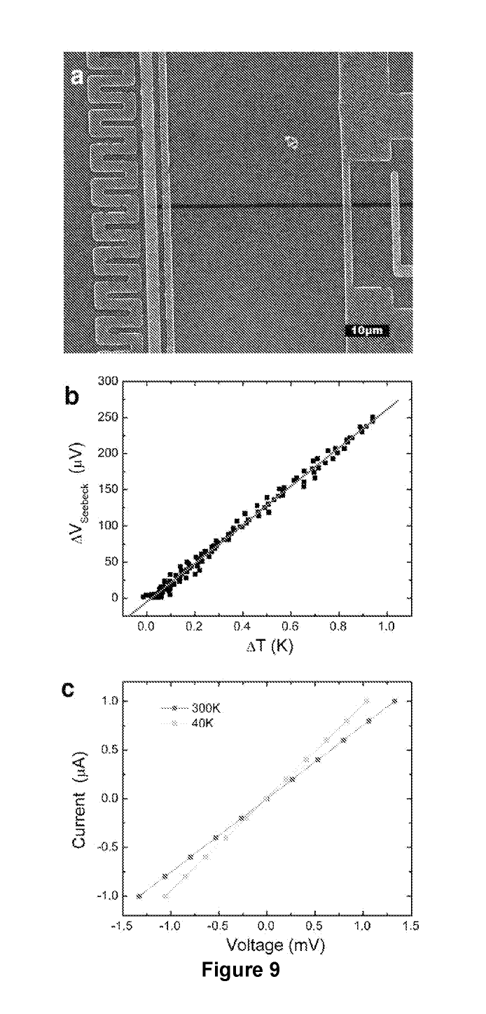

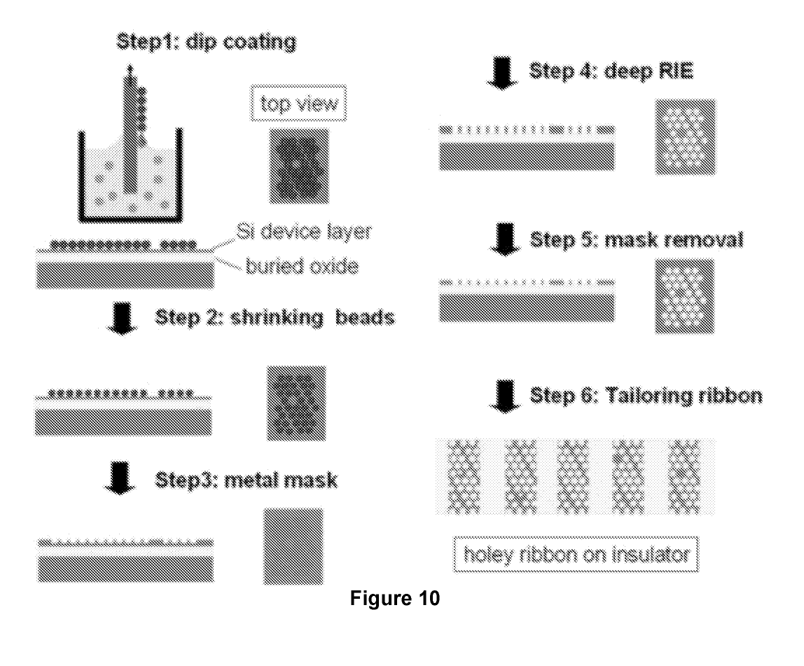

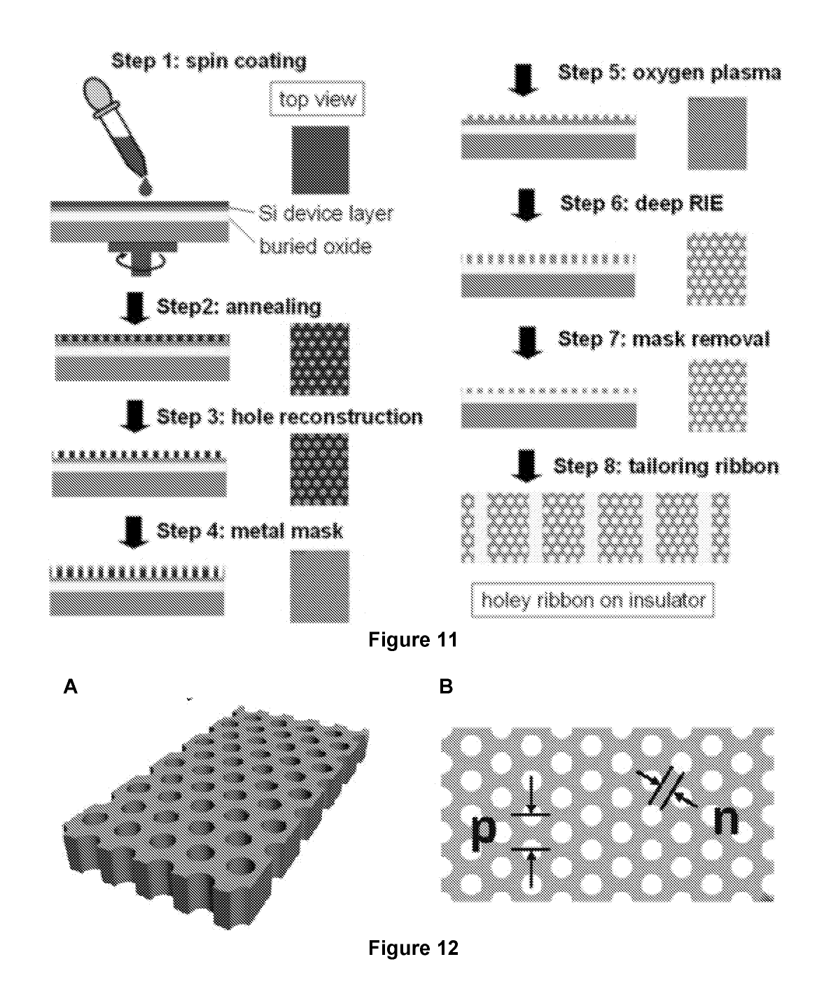

The electrical conductivity is measured by four point electrical device as shown in FIG. 9, The ribbons are usually 1-2 μm in width and 20-40 μm in length. Most uncertainty of ρ measurement is coming from the ribbon width measurement which can vary up to 3% within the measured length. Since the uncertainty from electrical measurement noise is less than 0.1%, we define the uncertainty of p measurement is 3%.

For thermopower measurement, the inner two Pt electrodes are connected to Keithley 2182A nanovoltmeter (Keithley Instruments, Inc., Cleveland, Ohio) for Seebeck voltage measurement while heating current is applied to heating coil by Keithley 236 source measurement unit. The local temperature is measured by four probe resistance of the inner Pt electrode. As described in previous study (8), the error of this measurement is estimated at less than 5% due to possible systematic error of this method, which is applied in the S measurement here.

### REFERENCES CITED

1. L. E. Bell, Science (Washington, D.C., United States) 321, 1457 (2008).
2. T. M. Tritt, H. Boettner, L. Chen, MRS Bulletin 33, 366 (2008).
3. J. Yang, T. Caillat, MRS Bulletin 31, 224 (2006).
4. T. C. Harman, P. J. Taylor, M. P. Walsh, B. E. LaForge, Science (Washington, D.C., United States) 297, 2229 (2002).
5. F. Hsu Kuei et al., Science (New York, N.Y.) 303, 818 (2004).
6. R. Venkatasubramanian, E. Slivola, T. Colpitts, B. O'Quinn, Nature (London, United Kingdom) 413, 597 (2001).
7. A. I. Boukai et al., Nature (London, United Kingdom) 451, 168 (2008).
8. A. I. Hochbaum et al., Nature (London, United Kingdom) 451, 163 (2008).
9. G. J. Snyder, E. S. Toberer, Nature Materials 7, 105 (2008).
10. L. Weber, E. Gmelin, Applied Physics A: Solids and Surfaces A53, 136 (1991).
11. G. Gesele, J. Linsmeier, V. Drach, J. Fricke, R. Arens-Fischer, Journal of Physics D: Applied Physics 30, 2911 (1997).
12. R. G. Mathur, R. M. Mehra, P. C. Mathur, Journal of Applied Physics 83, 5855 (1998).
13. A. Yamamoto, H. Takazawa, T. Ohta, International Conference on Thermoelectrics 18th, 428 (1999).
14. D. Li et al., Applied Physics Letters 83, 2934 (2003).
15. R. Chen et al., Physical Review Letters 101, 105501/1 (2008).
16. S. Park, B. Kim, J.-Y. Wang, T. P. Russell, Advanced Materials (Weinheim, Germany) 20, 681 (2008).
17. L. Shi et al., Journal of Heat Transfer 125, 881 (2003).
18. Y. S. Ju, K. E. Goodson, Applied Physics Letters 74, 3005 (1999).
19. D. G. Cahill, S. K. Watson, R. O. Pohl, Physical Review B: Condensed Matter and Materials Physics 46, 6131 (1992).
20. C. Chiritescu et al., Science (Washington, D.C., United States) 315, 351 (2007).
21. A. Majumdar, Microscale Thermophysical Engineering 2, 5 (1998).
22. Q. Hao, G. Chen, M.-S. Jeng, Journal of Applied Physics 106, 114321/1 (2009).
23. Y. Cui, Z. Zhong, D. Wang, W. U. Wang, C. M. Lieber, Nano Letters 3, 149 (2003).
24. H. Haick, P. T. Hurley, A. I. Hochbaum, P. Yang, N. S. Lewis, Journal of the American Chemical Society 128, 8990 (2006).
25. M. Ben-Chorin, F. Moeller, F. Koch, W. Schirmacher, M. Eberhard, Physical Review B: Condensed Matter and Materials Physics 51, 2199 (1995).
26. S. K. Bux et al., Advanced Functional Materials 19, 2445 (2009).

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

1. A method of making a nano structured ordered porous silicon, the method comprising:
forming an ordered polymeric nanostructure on a silicon-on-insulator substrate;
depositing a nanoscale metal film on the ordered polymeric nanostructure on a silicon layer of the silicon-on-insulator substrate;
removing the ordered polymeric nanostructure from the silicon layer of the silicon-on-insulator substrate to form a silicon etching metal mask;
etching the silicon through the metal mask to form the nanostructured ordered porous silicon;
removing the metal mask from the etched nanostructured ordered porous silicon; and
releasing the nanostructured ordered porous silicon from the remaining silicon-on-insulator substrate.

2. The method of claim 1, wherein the nanostructured ordered porous silicon consists essentially of single crystal porous silicon having uniform nanoscale pore size and separation.

3. The method of claim 1, wherein the forming the ordered polymeric nanostructure on the silicon-on-insulator substrate comprises assembling polystyrene nanospheres into a closed-packed monolayer by dip-coating onto a silicon device layer of the silicon-on-insulator substrate.

4. The method of claim 3, further comprising applying an oxygen plasma to the nanospheres until they are separated from each other.

5. The method of claim 4, further comprising e-beam evaporating a thin layer of chromium onto the silicon device layer, followed by stripping off the nanospheres with sonication in an organic solvent to form the metal mask.

6. The method of claim 5, further comprising etching the silicon device layer through the metal mask to form the nanostructured ordered porous silicon.

7. The method of claim 6, wherein the etching is done by anisotropic DRIE.

8. The method of claim 7, further comprising removing the metal mask from the etched nanostructured ordered porous silicon, and releasing the nanostructured ordered porous silicon from the remaining silicon-on-insulator substrate.

9. The method of claim 8, wherein nanostructured ordered porous silicon is released from substrate by etching off the buried oxide layer in hydrofluoric acid (HF) vapor.

10. The method of claim 9, wherein the released nanostructured ordered porous silicon is formed into a ribbon by standard photolithography prior to the release.

11. The method of claim 10, wherein the ribbon of nanostructured ordered porous silicon is about 1 to 3 μm wide by 20 to 50 μm long, and about 100 nm thick.

12. The method of claim 11, wherein the ribbon of nanostructured ordered porous silicon has a hexagonal holey pattern having a pitch of equal to or more than about 140 nm.

13. The method of claim 11, wherein the ribbon of nanostructured ordered porous silicon has a hexagonal holey pattern having a pitch of equal to or more than about 350 nm.

14. The method of claim 1, wherein the forming the ordered polymeric nanostructure on the silicon-on-insulator substrate comprises spin coating polystyrene-block-poly(4-vinylpyridine) (S4VP) copolymer mixed with 40 wt % polystyrene homopolymer onto a silicon device layer of the silicon-on-insulator substrate.

15. The method of claim 14, further comprising annealing the spun-on coating in tetrahydrofuran (THF) vapor.

16. The method of claim 15, further comprising surface reconstructing a long-range ordered hexagonally packed holey structure.

17. The method of claim 16, wherein the ribbon of nanostructured ordered porous silicon has a hexagonal holey pattern having a pitch of equal to or more than about 55 nm.

18. The method of claim 2, wherein the essentially of single crystal porous silicon having uniform nanoscale pore size and separation has thermoelectric material properties of a phonon glass and an electron crystal.

19. The method of claim 18, The nanostructured ordered porous silicon of claim 1, wherein the nanostructured ordered porous silicon has a ZT value equal to or more than about 0.4 at room temperature.

20. The method of claim 19, The nanostructured ordered porous silicon of claim 10, wherein the nanostructured ordered porous silicon has a ZT value equal to or more than about 0.6 at room temperature.
